(19) United States
(12) Patent Application Publication
(10) Pub. No.: US 2009/0243016 A1
(43) Pub. Date: Oct. 1, 2009

(54) SEMICONDUCTOR DEVICE

(75) Inventors: Hideaki Kawahara, Tokyo (JP); Hiroyuki Tomomatsu, Oita-ken (JP)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 12/412,834

(22) Filed: Mar. 27, 2009

(30) Foreign Application Priority Data
Mar. 27, 2008 (JP) 2008-083799

(51) Int. Cl. H01L 31/0216; H01L 31/105

(52) U.S. Cl. 257/435; 257/458; 257/466; 257/E31.122; 257/E31.061

(57) ABSTRACT

An apparatus is provided. The apparatus generally comprises a photoreceptive region and a circuit region formed in a substrate. A multilayer wiring region is then formed on the substrate over at least a portion of the circuit region. The multilayer wiring region includes a wiring layer and a light-blocking layer. The wiring layer is coupled to the circuit region, and the light-blocking wall has a metal layer that is arranged along at least a portion of the perimeter of the photoreceptive region and that is formed in the same process step as the wiring layer.

### CROSS-REFERENCE TO RELATED APPLICATIONS

This patent application claims priority from Japanese Patent Application No. 2008-083799, filed 27 Mar. 2008, the entirety of which is incorporated herein by reference for all purposes.

### TECHNICAL FIELD

The invention relates generally to a semiconductor and, more particularly, to a PIN photodiode.

### BACKGROUND

A PIN photodiode is an element that converts incident light into a photoelectric current; it has a P-I-N structure wherein an Intrinsic layer (a high-resistance epitaxial layer or the like) is included between a P-type semiconductor and an N-type semiconductor. The principle of operation is that when light with greater energy than the energy band gap is irradiated on silicon (Si) having a reverse-biased PIN structure, electron-hole pairs are generated within the silicon crystal, and these pairs migrate as charge carriers: the electrons to the N-layer and the holes to the P-layer, thus outputting currents in opposite directions.

An example of a conventional photodiode can be seen at Japanese Patent Application No. 2001-320079.

### SUMMARY

A preferred embodiment of the present invention, accordingly, provides a semiconductor device. The semiconductor device comprises at least one photoreceptive element region formed in a semiconductor region, at least one circuit element region formed in a semiconductor region, and a multilayer wiring region formed on the semiconductor regions excluding the photoreceptive element region; wherein the multilayer wiring region includes a multilayer structure metal wiring layer electrically connected to a circuit element of the circuit element region, and a light-blocking wall that blocks light from the outside; wherein the light-blocking wall includes a multilayer structure metal layer that is arranged along the perimeter of the photoreceptive element region and is formed in the same step as the multilayer structure metal wiring layer.

The light-blocking wall can be arranged along the perimeter of the circuit element region or of a semiconductor chip. Furthermore, the multilayer wiring region can include at least one light-blocking metal wiring layer in the uppermost layer, with the light-blocking wall being arranged along the perimeter of the light-blocking metal wiring layer. Furthermore, the light-blocking wall can be formed with an intermittently separated hole shape, in which case multiple hole-configuration light-blocking walls are arranged as multiple rows in a zigzag form.

Preferably the light-blocking wall includes at least an upper metal layer, a lower metal layer, and a metal plug within a via hole formed in an insulation film between the upper and lower metal layers. Preferably the upper metal layer is connected to the light-blocking metal wiring layer of the uppermost layer by a plug.

In accordance with a preferred embodiment of the present invention, the entrance of unnecessary light into the circuit element region is prevented by providing a light-blocking wall along the perimeter of the photoreceptive element region, so that circuit malfunctions can be prevented. Furthermore, the light-blocking wall is fabricated using the same process, so that the light-blocking wall can be formed easily without increasing the manufacturing steps.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and the specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A is a plan view showing the a semiconductor device in accordance with a preferred embodiment of the present invention;

FIG. 1B is a cross section view of FIG. 1A along line A1-A1 thereof;

FIGS. 2A through 2D are diagrams showing an example of the manufacturing process for the light-blocking wall in accordance with a preferred embodiment of the present embodiment;

FIG. 3A shows an example of a light-blocking wall formed on the electroconductive region on a silicon substrate;

FIG. 3B is a diagram showing an example of a light-blocking wall formed on the insulation region of a silicon substrate;

FIG. 4A is a plan view showing a semiconductor device in accordance with a preferred embodiment of the present invention;

FIG. 4B is a cross section view of FIG. 4A along line A2-A2 thereof; and

FIG. 5 is a diagram showing an example of the semiconductor device of the present embodiment applied to an optical pickup.

### DETAILED DESCRIPTION

Refer now to the drawings wherein depicted elements are, for the sake of clarity, not necessarily shown to scale and wherein like or similar elements are designated by the same reference numeral through the several views.

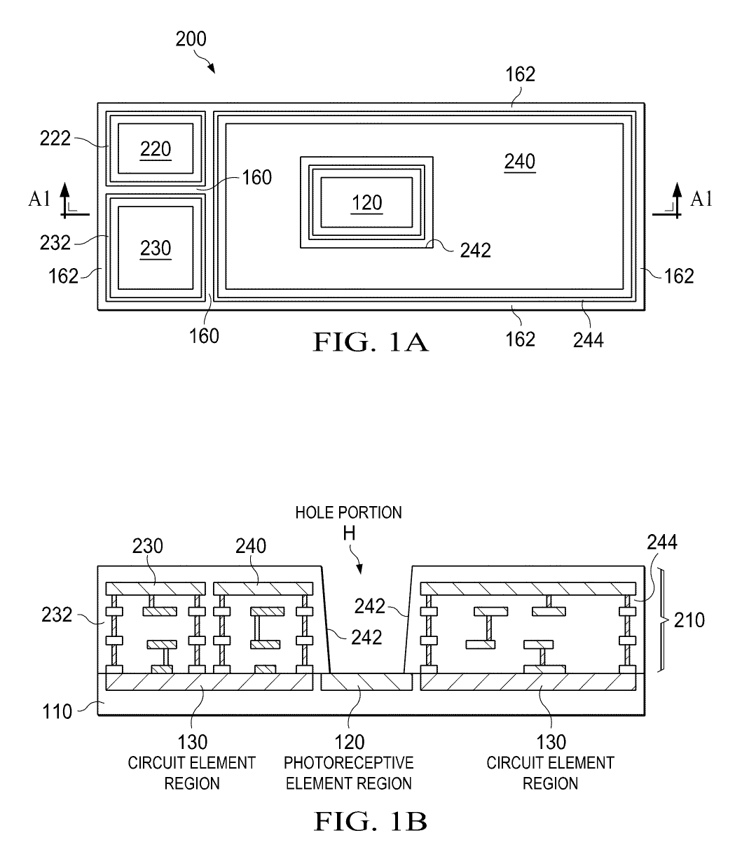

FIG. 1A is a plan view showing a semiconductor device in accordance with a preferred embodiment of the present invention, and FIG. 1B is a cross section along line A1-A1 thereof. The semiconductor device 200 includes a silicon substrate 110 (including an epitaxial semiconductor layer or the like formed on or in the substrate), and a photoreceptive element region 120 (which generally comprises a PIN photodiode), and a peripheral circuit region 130 (which generally includes a circuit that amplifies the photoelectric current that has been generated by the PIN photodiode).

A multilayer wiring region 210 that includes multilayer structure wiring layers with insulation films interposed therebetween formed on silicon substrate 110. A rectangular hole H is formed in multilayer wiring region 210 such that photoreceptive element region 120 is exposed. Rectangular light-blocking metal wiring layers 220 and 230 (patterned from aluminum (Al) or the like metal layer) and a light-blocking metal wiring layer 240 (in which a hole is formed corresponding to the outline of hole H of photoreceptive element region 120) are formed as the uppermost layer of multilayer wiring region 210. In addition, the chip surface, which includes light-blocking metal wiring layers 220, 230, and 240 and photoreceptive element region 120, is covered with a protective film of a silicon oxide, silicon nitride, or the like.

The light entering hole H passes through the protective film and irradiates the region 120 formed in the surface of the silicon substrate. When region 120 is a PIN photodiode, a reverse-bias voltage can applied to the region 120 to form a depletion region therein, and when light enters the depletion region, electron-hole pairs are generated. The electrons and holes migrate to the reverse-biased electrodes, and photoelectric current is generated. The currents are amplified by the circuit element region 130 and are output to the outside from a terminal (not shown).

A feature of the device 200 is that multilayer wiring region 210 is provided with a linear pattern of light-blocking walls 222, 232, and 242 to block light from the outside. Light-blocking wall 242 is arranged near the side wall of hole H such that it surrounds the perimeter of the region 120, which corresponds to the route of the light entering peripheral circuit region 130. Light-blocking wall 244 is arranged along the outline or the outer portion of light-blocking metal wiring layer 240. Light-blocking wall 222 is arranged along the outline or the outer portion of light-blocking metal wiring layer 220. Light-blocking wall 232 is arranged along the outline or the outer portion of light-blocking metal wiring layer 230. Portions of light-blocking walls 222, 232, and 244 also serve as light-blocking walls arranged along the perimeter of the chip.

Multilayer wiring region 210 is an example of metal wiring layers with a 4-layer structure. Preferably, the light-blocking walls 222, 232, and 244 include metal layers with a 4-layer structure just as with the metal wiring layers with a 4-layer structure. The light-blocking walls 222, 232, and 244 are formed using the same process as with the metal wiring layers, so that a new process is not required to form the light-blocking walls 222, 232, and 244; in other words, it is necessary to change only the wiring pattern when the metal wiring layers are formed and the mask pattern when the via hole is formed in the interlayer insulation film. Preferably, the metal wiring layers that comprise the light-blocking walls 222, 232, and 244 include a via contact or a plug that fills the via hole formed in the interlayer insulation film.

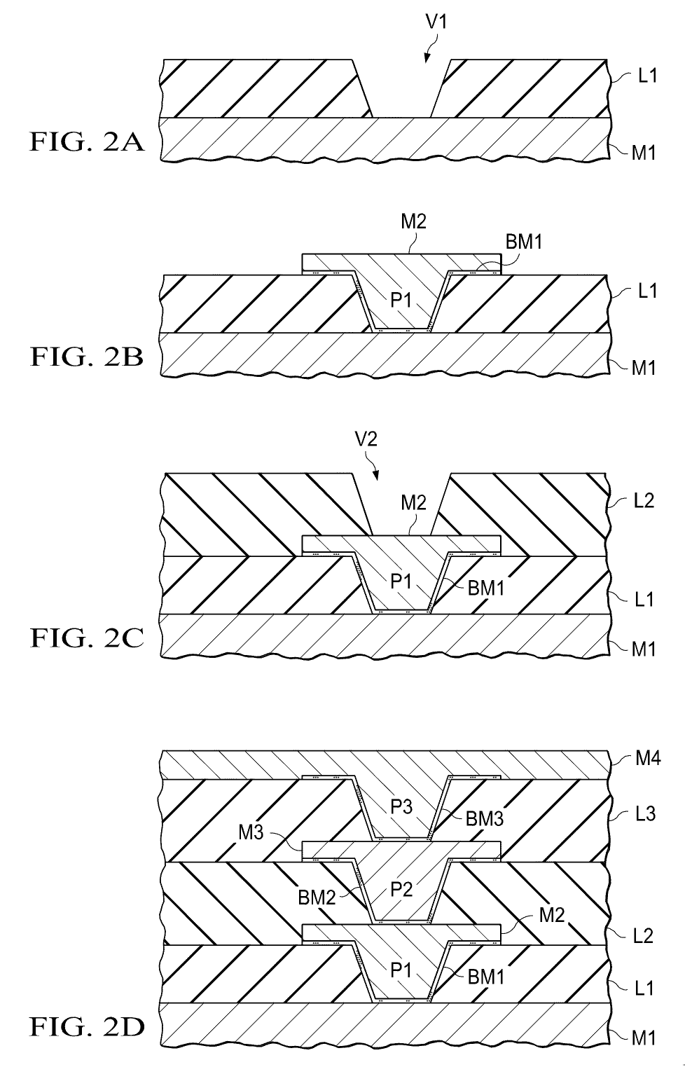

FIGS. 2A through 2D depict an example of the process of manufacturing light-blocking walls with a 4-layer structure are shown. In FIG. 2A, a first metal layer M1 pattern of aluminum (Al) or the like is formed on a silicon substrate, and a first interlayer insulation film L1 of a silicon oxide film or of borophosphosilicate glass (BPSG) is formed on a region that includes first metal layer M1. A first via hole V1 is also formed in interlayer insulation film L1. In FIG. 2B, a barrier metal BM1 of titanium tungstide (TiW) or the like is formed, and a second metal layer M2 of copper (Cu) or the like is formed such that a plug P1 is formed in via hole V1. Then, barrier metal BM1 and second metal layer M2 are patterned. In FIG. 2C, a second interlayer insulation film L2 is formed, and a second via hole V2 is formed at a position aligned with second metal layer M2. In FIG. 2D, a barrier metal BM2 is formed, and a third metal layer M3 is formed such that a plug P2 is formed within via hole V2. Barrier metal BM2 and third metal layer M3 are patterned. Subsequently, in the same way, a third interlayer insulation film L3 is formed, and the uppermost layer, a fourth metal layer, that is, light-blocking metal wiring layers 220 230, or 240, is formed by means of the plug P3 of a third via hole V3.

Preferably, the interlayer insulation films undergos a planarization process; for example, the films can be formed by applying a liquefied insulating substance such as BPSG or can be planarized by chemical mechanical planarization (CMP) or the like. In addition, the size and shape of the via hole formed in the interlayer insulation films can be selected appropriately depending on the material of the metal layer used, the film thickness of the interlayer insulation film, or the like. To form the metal layers of light-blocking walls in a linear pattern, it is preferable that copper (Cu) be used, due to its good filling characteristics, to generally prevent voids from occurring in the plug or the via contact. Furthermore, in the previous example, barrier metals BM1-BM3 were formed underlying the second through fourth metal layers; however, a barrier metal may be eliminated. Furthermore, in the previous example, the plug and the metal layer were formed in the same step; however, for example, if different multilayer wiring processes are used to form the plug formed in the via hole and the metal layer formed on the plug with different materials, then the metal layer and the plug of the light-blocking wall will exhibit the same changes.

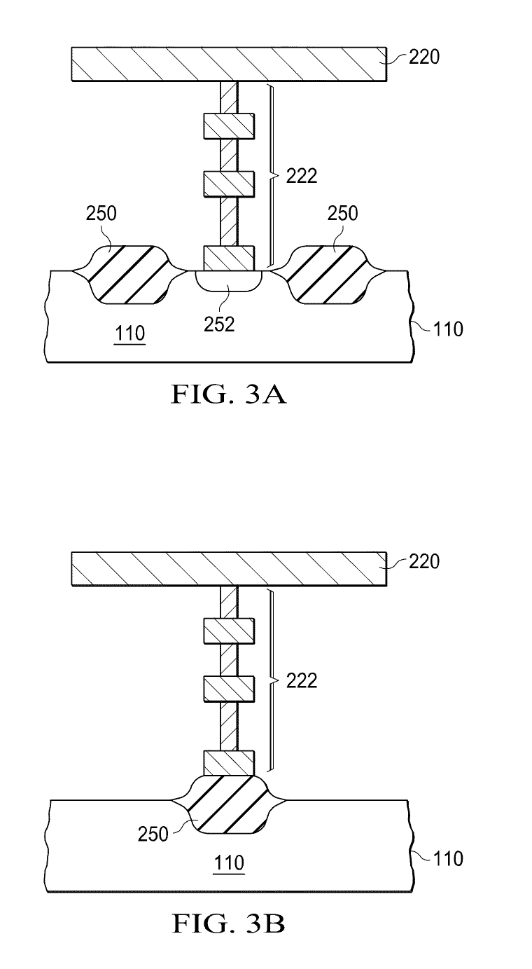

FIG. 3 shows an example of the arrangement of a light-blocking wall, where light-blocking wall 222 is used as the example. As shown in FIG. 3A, light-blocking wall 222 is arranged such that it is in ohmic contact with a high-concentration impurity region 252 within an active region demarcated by a field oxide film 250 on a silicon substrate 110. In this case, light-blocking wall 222 can provide a current path between high-concentration impurity region 252 and light-blocking metal wiring layer 220.

Furthermore, as shown in FIG. 3B, light-blocking wall 222 can be formed on a field oxide film 250 on silicon substrate 110. Light-blocking wall 222 is electrically connected to light-blocking metal wiring layer 220, but it is electrically insulated from the substrate. An ESD or a high current is sometimes applied to light-blocking wall 222, but due to the film thickness of the field oxide film, the influence of the electrical field on the active region can be prevented.

A light-blocking wall (as described above) that reflects light from the outside is formed in the multilayer wiring region; thus, for example, the light that irradiates outer edge 162 and the gap 160 between light-blocking metal layers 220, 230 and 240 is blocked by light-blocking walls 222, 232 and 244. Therefore, the entrance of light into circuit element region 130 can be generally prevented. Furthermore, most of the light entering hole H is received by photoreceptive element region 120, but the light that irradiates the side walls of hole H is blocked by light-blocking wall 242, so that the entrance of light into peripheral circuit region 130 can be prevented. Furthermore, light irradiating the chip surface is blocked by light-blocking metal wiring layers 220, 230 and 240 of the uppermost layer. Thus, circuit element malfunctions are prevented and the sensitivity of the photoreceptive element can be maintained at a high level.

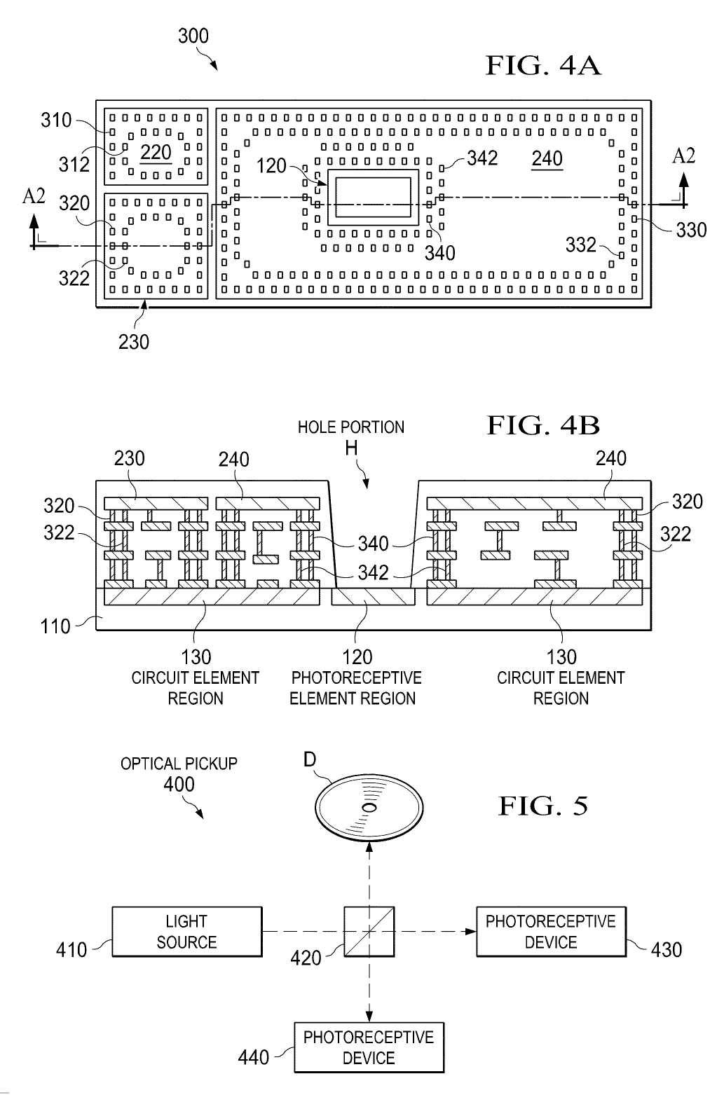

Turning to FIG. 4, a semiconductor device 300 can be seen. With device 300, the light-blocking walls are in a multiple-hole configuration or in the form of rivets, with two rows of light-blocking walls with a hole configuration arranged to form a zigzag pattern. Preferably, a light-blocking wall 310 with a hole configuration is arranged along the perimeter of light-blocking metal wiring layer 220, and a light-blocking wall 312 with a hole configuration is arranged further inward. In the same way, a light-blocking wall 320 with a hole configuration is arranged along the perimeter of light-blocking metal wiring layer 230, and a light-blocking wall 322 with a hole configuration is arranged further inward. In addition, light-blocking walls 330, 332 with a hole configuration are arranged along the perimeter of light-blocking metal wiring layer 240, with 2 rows of light-blocking walls 340, 342 with a hole configuration arranged such that photoreceptive element region 120 is enclosed. Preferably, the interior light-blocking walls are arranged such that they are at the center of the pitch of the exterior light-blocking walls with a hole configuration on the outside, or are arranged reversely.

With the linear pattern of plugs shown in FIG. 1, voids may easily appear if they are not well filled. If a void is formed within a plug, that portion will be insufficiently flat, so that during the processes subsequent to the via contact process, pattern defects occur easily. In FIG. 4, the linear pattern is separated to form a multiple-hole configuration, so there is an advantage in that it is difficult for a void to form in the plug. Accordingly, device 300 is appropriate for an aluminum (Al) wiring process, which has a poorer filling characteristic. In this case, tungsten (W) can be used for the plugs. In addition, the previous example used two rows of light-blocking walls with a hole configuration, but this is only one example: there can be one row, or three rows, and it is not required that there be the same number of rows for all of the light-blocking walls. The light-blocking walls can be a mixture of the light-blocking walls of device 100 and the light-blocking walls with a hole configuration of device 300.

With devices 100 and 300, one photoreceptive element region was formed on the silicon substrate; however, multiple photoreceptive elements or photoreceptive element regions can be formed, and light-blocking walls can be formed in the multilayer wiring region such that each photoreceptive element region is enclosed.

Furthermore, as described, the light-blocking walls were formed respectively at the perimeter of the photoreceptive element region, the perimeter of the peripheral circuit region, and the perimeter of the chip; however, it is not required that the light-blocking walls be formed in all of these positions; the light-shielding walls can be formed in some of these positions. Furthermore, the number of metal layers forming light-blocking walls was identical to the number of metal wiring layers of the multilayer wiring regions; however, there can be fewer light-blocking walls than metal wiring layers of the multilayer wiring regions. In this case, near the silicon substrate, it will be difficult for light to enter at a large oblique angle, so that there can be a light-blocking wall with a metal layer omitted adjacent to the silicon substrate.

Now, turning to FIG. 5, an example of the application of a semiconductor device can be seen. Preferably, the structure of an optical pickup 400 is shown. Optical pickup 400 is a device that optically reads data recorded on, or that optically writes data to, a rotating disk. Optical pickup 400 generally comprises a light source 410 that includes a laser element or a laser diode element 410 that emits blue light, a splitter 420, and photoreceptive devices 430 and 440. Splitter 420 reflects blue light emitted from light source 410 onto a disk D and transmits a portion of that light to photoreceptive element 430, and transmits reflected light from disk D to photoreceptive device 440. Photoreceptive device 430 monitors the light output from light source 410, and the optical output of the blue light is stabilized based on the result thereof. Photoreceptive device 440 monitors the light reflected from disk D and performs focus and tracking control based on the result thereof. In addition, photoreceptive device 440 is used in the reading of data that is written on disk D.

The semiconductor devices 200 and 300 are applicable to photoreceptive devices 430 and 440 of this type. Photoreceptive devices 430 and 440 include a PIN photodiode for the purpose of receiving the blue light, and devices 430 and 440 integrate on one silicon chip a circuit that amplifies or processes signals detected by the PIN photodiode. The integrated circuit includes multiple MOS transistors or the like.

Having thus described the present invention by reference to certain of its preferred embodiments, it is noted that the embodiments disclosed are illustrative rather than limiting in nature and that a wide range of variations, modifications, changes, and substitutions are contemplated in the foregoing disclosure and, in some instances, some features of the present invention may be employed without a corresponding use of the other features. Accordingly, it is appropriate that the appended claims be construed broadly and in a manner consistent with the scope of the invention.

1. An apparatus comprising:
a photoreceptive region formed in a substrate;
a circuit region formed in the substrate; and
a multilayer wiring region formed on the substrate over at least a portion of the circuit region, wherein the multilayer wiring region includes:
a wiring layer that is coupled to the circuit region; and
a light-blocking wall having a metal layer that is arranged along at least a portion of the perimeter of the photoreceptive region and that is formed in the same process step as the wiring layer.

2. The apparatus of claim 1, wherein the multilayer wiring region further comprises a light-blocking metal wiring layer.

3. The apparatus of claim 1, wherein the light-blocking wall is formed in an intermittently separated pattern.

4. The apparatus of claim 2, wherein the pattern is multiple rows in a zigzag pattern.

5. The apparatus of claim 1, wherein the light-blocking wall further comprises:
an upper metal layer;
a lower metal layer;
an insulation film between the upper metal layer and the lower metal layer;
a via formed in the insulating film; and
a metal plug within the via.

6. The apparatus of claim 5, wherein the upper metal layer is coupled to the metal wiring layer by a second metal plug.

7. A apparatus having:
a photoreceptive region formed in a substrate, wherein the photoreceptive region includes a PIN photodiode;
a circuit region formed in the substrate, wherein the circuit region includes an amplifier circuit that is adapted to amplify a photoelectric current generated by the PIN photodiode;
a multilayer wiring region formed on the substrate over at least a portion of the circuit region, wherein the multilayer wiring region includes:
a wiring layer that is coupled to the circuit region; and
a light-blocking wall having a first metal layer and a second metal layer with an insulating layer therebetween, wherein the insulating layer has a via with a metal plug formed therein.

8. The apparatus of claim 7, wherein the light-blocking wall is formed in an intermittently separated pattern.

9. The apparatus of claim 7, wherein the pattern is multiple rows in a zigzag pattern.
